(19) United States
(12) Patent Application Publication
(10) Pub. No.: US 2013/0307105 A1
(43) Pub. Date: Nov. 21, 2013

(54) IMAGE-SENSING MODULE FOR REDUCING ITS WHOLE THICKNESS

(71) Applicant: CHI-HSING HSU, NEW TAIPEI CITY (TW)

(72) Inventor: CHI-HSING HSU, NEW TAIPEI CITY (TW)

(73) Assignee: AZUREWAVE TECHNOLOGIES, INC., NEW TAIPEI CITY (TW)

(21) Appl. No.: 13/531,498

(22) Filed: Jun. 23, 2012

(30) Foreign Application Priority Data
May 16, 2012 (TW) 101117357

(51) Int. Cl. H01L 31/0232

(52) U.S. Cl. 257/432; 257/E31.127

(57) ABSTRACT

An image-sensing module for reducing its whole thickness includes a substrate unit, a carrier unit, an image-sensing unit and a lens unit. The substrate unit includes a substrate body and a through opening passing through the substrate body. The carrier unit includes a carrier body disposed on the bottom surface of the substrate body and corresponding to the through opening. The image-sensing unit includes an image-sensing element disposed on the top surface of the carrier body and embedded in the through opening. The lens unit includes an opaque frame disposed on the top surface of the carrier body to surround the image-sensing element and a lens connected to the opaque frame and positioned above the image-sensing element. Hence, the whole thickness of the image-sensing module can be reduced due to the design of placing the substrate body, the image-sensing element and the opaque frame on the carrier body.

### BACKGROUND OF THE INVENTION

1. Field of the Invention

The instant disclosure relates to an image-sensing module, and more particularly, to an image-sensing module for reducing its whole thickness.

2. Description of Related Art

The advantage of CMOS (Complementary Metal-Oxide-Semiconductor) is low power consumption and small size, thus the CMOS image-sensing chip package module can integrate into portable electronic device with small size such as mobile phone and notebook. However, the whole thickness of the image-sensing chip package module of the prior art cannot be reduced.

### SUMMARY OF THE INVENTION

One aspect of the instant disclosure relates to an image-sensing module for reducing its whole thickness.

One of the embodiments of the instant disclosure provides an image-sensing module for reducing its whole thickness, comprising: a substrate unit, a carrier unit, an image-sensing unit and a lens unit. The substrate unit includes a substrate body and at least one through opening passing through the substrate body. The carrier unit includes a carrier body disposed on the bottom surface of the substrate body and corresponding to the at least one through opening, wherein the carrier body is electrically connected to the substrate body. The image-sensing unit includes at least one image-sensing element disposed on the top surface of the carrier body and embedded in the at least one through opening, wherein the at least one image-sensing element is electrically connected to the carrier body and surrounded by the substrate body. The lens unit includes an opaque frame disposed on the top surface of the carrier body to surround the at least one image-sensing element and a lens connected to the opaque frame and positioned above the at least one image-sensing element.

Moreover, the image-sensing module further comprises a first conductive unit and a second conductive unit, wherein the first conductive unit includes a plurality of first conductive elements electrically connected between the at least one image-sensing element and the carrier body, and the second conductive unit includes a plurality of second conductive elements electrically connected between the carrier body and the substrate body.

Furthermore, the carrier unit includes a plurality of first top conductive tracks disposed on the top surface of the carrier body, the image-sensing unit includes a plurality of conductive pads disposed on the top surface of the at least one image-sensing element and respectively corresponding to the first top conductive tracks, and each conductive pad of the image-sensing unit is electrically connected to each corresponding first top conductive track of the carrier unit through each corresponding first conductive element.

In addition, the carrier unit includes a plurality of first top conductive tracks disposed on the top surface of the carrier body, a plurality of first bottom conductive tracks disposed on the bottom surface of the carrier body and respectively corresponding to the first top conductive tracks, a plurality of first outer conductive tracks disposed on the top surface of the carrier body and respectively corresponding to the first bottom conductive tracks, a plurality of first inner conductive channels embedded in the carrier body, and a plurality of first outer conductive channels embedded in the carrier body, each first inner conductive channel is electrically connected between each corresponding first top conductive track and each corresponding first bottom conductive track, each first outer conductive channel is electrically connected between each corresponding first bottom conductive track and each corresponding first outer conductive track, the image-sensing unit includes a plurality of conductive pads disposed on the top surface of the at least one image-sensing element and respectively corresponding to the first top conductive tracks, and each conductive pad of the image-sensing unit is electrically connected to each corresponding first top conductive track of the carrier unit through each corresponding first conductive element.

Moreover, the substrate unit includes a plurality of second bottom conductive tracks disposed on the bottom surface of the substrate body and respectively corresponding to the first top conductive tracks, and each first top conductive track of the carrier unit is electrically connected to each corresponding second bottom conductive track of the substrate unit through each corresponding second conductive element.

Furthermore, the substrate unit includes a plurality of second bottom conductive tracks disposed on the bottom surface of the substrate body and respectively corresponding to the first top conductive tracks, a plurality of second top conductive tracks disposed on the top surface of the substrate body and respectively corresponding to the second bottom conductive tracks, and a plurality of second inner conductive channels embedded in the substrate body, each second inner conductive channel is electrically connected between each corresponding second bottom conductive track and each corresponding second top conductive track, and each first top conductive track of the carrier unit is electrically connected to each corresponding second bottom conductive track of the substrate unit through each corresponding second conductive element.

In addition, the substrate unit includes a plurality of second bottom conductive tracks disposed on the bottom surface of the substrate body and respectively corresponding to the first top conductive tracks, a plurality of second top conductive tracks disposed on the top surface of the substrate body and respectively corresponding to the second bottom conductive tracks, a plurality of second outer conductive tracks disposed on the bottom surface of the substrate body and respectively corresponding to the second top conductive tracks, a plurality of second inner conductive channels embedded in the substrate body, and a plurality of second outer conductive channels embedded in the substrate body, each second inner conductive channel is electrically connected between each corresponding second bottom conductive track and each corresponding second top conductive track, each second outer conductive channel is electrically connected between each corresponding second top conductive track and each corresponding second outer conductive track, and each first top conductive track of the carrier unit is electrically connected to each corresponding second bottom conductive track of the substrate unit through each corresponding second conductive element.

Therefore, the substrate body, the image-sensing element and the opaque frame are disposed on the top surface of the carrier body, thus the whole thickness of the image-sensing module can be reduced effectively.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, cross-sectional, schematic view of the image-sensing module for reducing its whole thickness according to the first embodiment of the instant disclosure;

FIG. 2 shows a lateral, cross-sectional, schematic view of the image-sensing module for reducing its whole thickness according to the second embodiment of the instant disclosure;

FIG. 3 shows a lateral, cross-sectional, schematic view of the image-sensing module for reducing its whole thickness according to the second embodiment of the instant disclosure;

FIG. 4 shows a lateral, cross-sectional, schematic view of the image-sensing module for reducing its whole thickness according to the second embodiment of the instant disclosure; and

FIG. 5 shows a lateral, cross-sectional, schematic view of the image-sensing element electrically connected to the carrier body through the first conductive elements according to the instant disclosure.

### DETAILED DESCRIPTION OF THE PREFERRED EMBODIMENTS

### First Embodiment

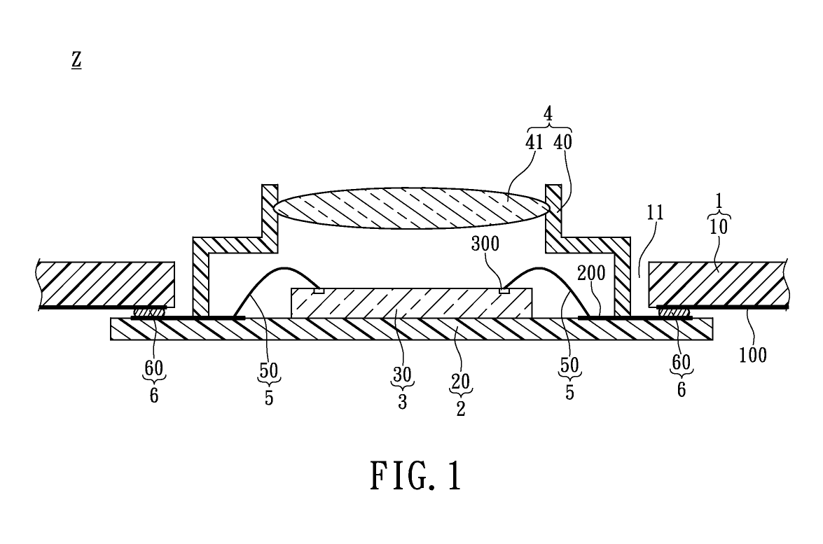

Referring to FIG. 1, where the first embodiment of the instant disclosure an image-sensing module Z for reducing its whole thickness, comprising: a substrate unit 1, a carrier unit 2, an image-sensing unit 3 and a lens unit 4.

The substrate unit 1 includes a substrate body 10 (such as a FPC (Flexible Printed Circuit)) and at least one through opening 11 passing through the substrate body 10. The carrier unit 2 includes a carrier body 20 (such as a PLCC (Plastic Leader Chip Carrier)) disposed on the bottom surface of the substrate body 10 and corresponding to the through opening 11, where the carrier body 20 is electrically connected to the substrate body 10. The image-sensing unit 3 includes at least one image-sensing element 30 (such as a CMOS (Complementary Metal-Oxide-Semiconductor)) disposed on the top surface of the carrier body 20 and embedded in the through opening 11, where the image-sensing element 30 is electrically connected to the carrier body 20 and surrounded by the substrate body 10. The lens unit 4 includes an opaque frame 40 disposed on the top surface of the carrier body 20 to surround the image-sensing element 30 and a lens 41 connected to the opaque frame 40 and positioned above the image-sensing element 30.

For example, the image-sensing module Z further comprises a first conductive unit 5 and a second conductive unit 6. The first conductive unit 5 includes a plurality of first conductive elements 50 (such as conductive wires) electrically connected or contacting between the image-sensing element 30 and the carrier body 20, and the second conductive unit 6 includes a plurality of second conductive elements 60 (such as solder balls or solder paste) electrically connected or contacting between the carrier body 20 and the substrate body 10. Moreover, the carrier unit 2 includes a plurality of first top conductive tracks 200 disposed on the top surface of the carrier body 20, the image-sensing unit 3 includes a plurality of conductive pads 300 disposed on the top surface of the image-sensing element 30 and respectively corresponding to the first top conductive tracks 200, and each conductive pad 300 of the image-sensing unit 3 is electrically connected to each corresponding first top conductive track 200 of the carrier unit 2 through each corresponding first conductive element 50. Furthermore, the substrate unit 1 includes a plurality of second bottom conductive tracks 100 disposed on the bottom surface of the substrate body 10 and respectively corresponding to the first top conductive tracks 200, and each first top conductive track 200 of the carrier unit 2 is electrically connected to each corresponding second bottom conductive track 100 of the substrate unit 1 through each corresponding second conductive element 60.

Therefore, the substrate body 10, the image-sensing element 30 and the opaque frame 40 are disposed on the top surface of the carrier body 20, thus the whole thickness of the image-sensing module can be reduced effectively.

### Second Embodiment

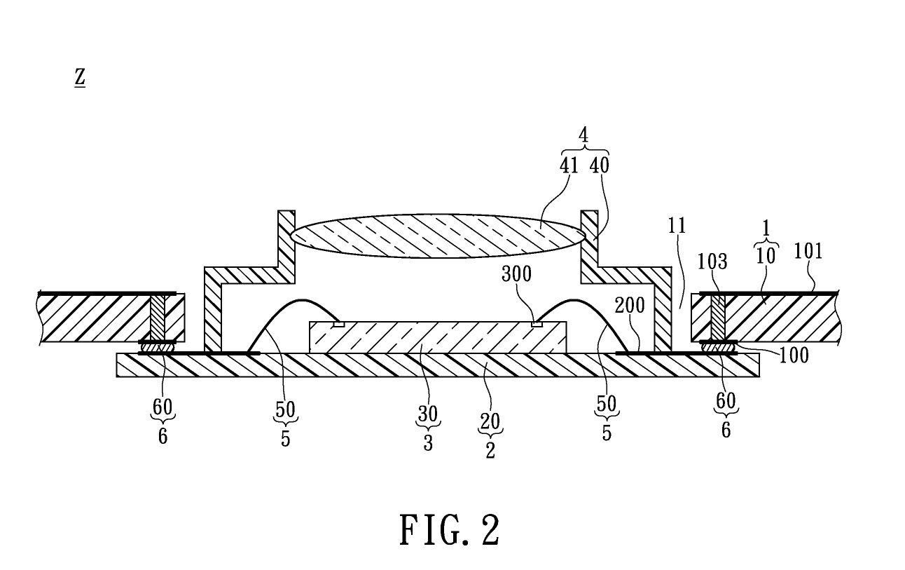

Referring to FIG. 2, where the second embodiment of the instant disclosure an image-sensing module Z for reducing its whole thickness, comprising: a substrate unit 1, a carrier unit 2, an image-sensing unit 3 and a lens unit 4. The substrate unit 1 includes a substrate body 10 and at least one through opening 11 passing through the substrate body 10. The carrier unit 2 includes a carrier body 20 disposed on the bottom surface of the substrate body 10 and corresponding to the through opening 11, where the carrier body 20 is electrically connected to the substrate body 10. The image-sensing unit 3 includes at least one image-sensing element 30 disposed on the top surface of the carrier body 20 and embedded in the through opening 11, where the image-sensing element 30 is electrically connected to the carrier body 20 and surrounded by the substrate body 10. The lens unit 4 includes an opaque frame 40 disposed on the top surface of the carrier body 20 to surround the image-sensing element 30 and a lens 41 connected to the opaque frame 40 and positioned above the image-sensing element 30. For example, the image-sensing module Z further comprises a first conductive unit 5 and a second conductive unit 6. The first conductive unit 5 includes a plurality of first conductive elements 50 electrically connected or contacting between the image-sensing element 30 and the carrier body 20, and the second conductive unit 6 includes a plurality of second conductive elements 60 electrically connected or contacting between the carrier body 20 and the substrate body 10.

Comparing FIG. 2 with FIG. 1, the difference between the second embodiment and the first embodiment is as follows: in the second embodiment, the substrate unit 1 includes a plurality of second bottom conductive tracks 100 disposed on the bottom surface of the substrate body 10 and respectively corresponding to the first top conductive tracks 200, a plurality of second top conductive tracks 101 disposed on the top surface of the substrate body 10 and respectively corresponding to the second bottom conductive tracks 100, and a plurality of second inner conductive channels 103 embedded in the substrate body 10. In addition, each second inner conductive channel 103 is electrically connected or contacting between each corresponding second bottom conductive track 100 and each corresponding second top conductive track 101, and each first top conductive track 200 of the carrier unit 2 is electrically connected to each corresponding second bottom conductive track 100 of the substrate unit 1 through each corresponding second conductive element 60.

Therefore, each conductive pad 300 of the image-sensing element 30 can be electrically connected to each corresponding second top conductive track 101 through each corresponding first conductive element 50, each corresponding first top conductive track 200, each corresponding second conductive element 60, each corresponding second bottom conductive track 100 and each corresponding second inner conductive channel 103 in sequence.

### Third Embodiment

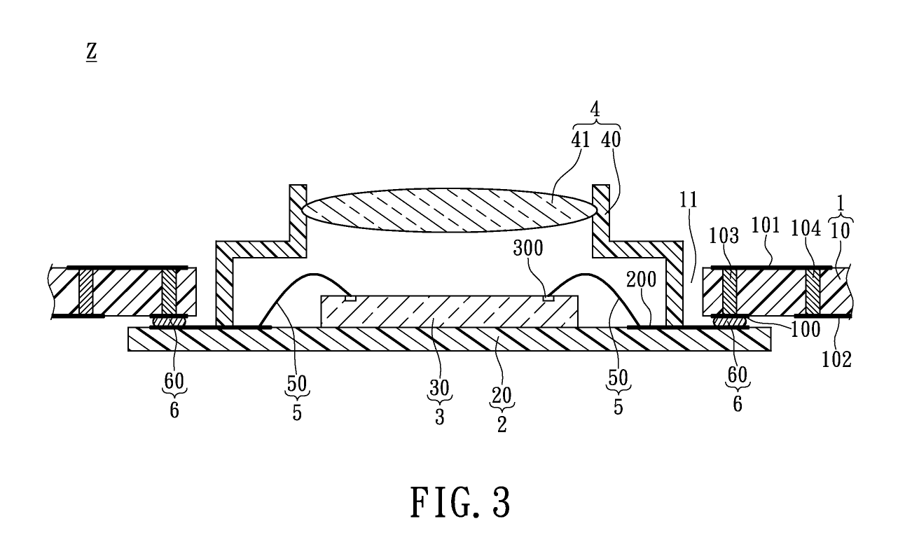

Referring to FIG. 3, where the third embodiment of the instant disclosure an image-sensing module Z for reducing its whole thickness, comprising: a substrate unit 1, a carrier unit 2, an image-sensing unit 3 and a lens unit 4. The substrate unit 1 includes a substrate body 10 and at least one through opening 11 passing through the substrate body 10. The carrier unit 2 includes a carrier body 20 disposed on the bottom surface of the substrate body 10 and corresponding to the through opening 11, where the carrier body 20 is electrically connected to the substrate body 10. The image-sensing unit 3 includes at least one image-sensing element 30 disposed on the top surface of the carrier body 20 and embedded in the through opening 11, where the image-sensing element 30 is electrically connected to the carrier body 20 and surrounded by the substrate body 10. The lens unit 4 includes an opaque frame 40 disposed on the top surface of the carrier body 20 to surround the image-sensing element 30 and a lens 41 connected to the opaque frame 40 and positioned above the image-sensing element 30. For example, the image-sensing module Z further comprises a first conductive unit 5 and a second conductive unit 6. The first conductive unit 5 includes a plurality of first conductive elements 50 electrically connected or contacting between the image-sensing element 30 and the carrier body 20, and the second conductive unit 6 includes a plurality of second conductive elements 60 electrically connected or contacting between the carrier body 20 and the substrate body 10.

Comparing FIG. 3 with FIG. 1, the difference between the third embodiment and the first embodiment is as follows: in the third embodiment, the substrate unit 1 includes a plurality of second bottom conductive tracks 100 disposed on the bottom surface of the substrate body 10 and respectively corresponding to the first top conductive tracks 200, a plurality of second top conductive tracks 101 disposed on the top surface of the substrate body 10 and respectively corresponding to the second bottom conductive tracks 100, a plurality of second outer conductive tracks 102 disposed on the bottom surface of the substrate body 10 and respectively corresponding to the second top conductive tracks 101, a plurality of second inner conductive channels 103 embedded in the substrate body 10, and a plurality of second outer conductive channels 104 embedded in the substrate body 10 and separated from the second inner conductive channels 103 by a predetermined distance. Moreover, each second inner conductive channel 103 is electrically connected or contacting between each corresponding second bottom conductive track 100 and each corresponding second top conductive track 101, each second outer conductive channel 104 is electrically connected or contacting between each corresponding second top conductive track 101 and each corresponding second outer conductive track 102, and each first top conductive track 200 of the carrier unit 2 is electrically connected to each corresponding second bottom conductive track 100 of the substrate unit 1 through each corresponding second conductive element 60.

Therefore, each conductive pad 300 of the image-sensing element 30 can be electrically connected to each corresponding second outer conductive track 102 through each corresponding first conductive element 50, each corresponding first top conductive track 200, each corresponding second conductive element 60, each corresponding second bottom conductive track 100, each corresponding second inner conductive channel 103, each corresponding second top conductive track 101 and each corresponding second outer conductive channel 104 in sequence.

### Fourth Embodiment

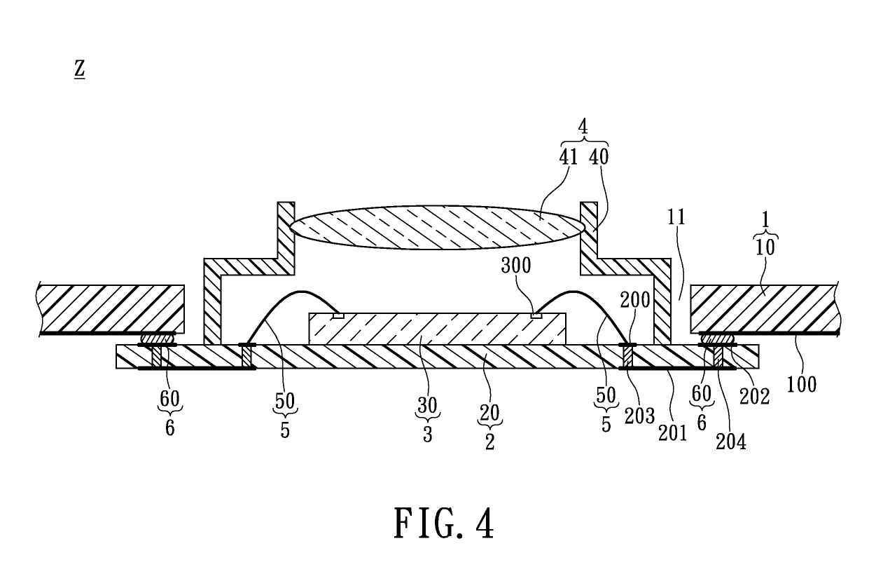

Referring to FIG. 4, where the fourth embodiment of the instant disclosure an image-sensing module Z for reducing its whole thickness, comprising: a substrate unit 1, a carrier unit 2, an image-sensing unit 3 and a lens unit 4. The substrate unit 1 includes a substrate body 10 and at least one through opening 11 passing through the substrate body 10. The carrier unit 2 includes a carrier body 20 disposed on the bottom surface of the substrate body 10 and corresponding to the through opening 11, where the carrier body 20 is electrically connected to the substrate body 10. The image-sensing unit 3 includes at least one image-sensing element 30 disposed on the top surface of the carrier body 20 and embedded in the through opening 11, where the image-sensing element 30 is electrically connected to the carrier body 20 and surrounded by the substrate body 10. The lens unit 4 includes an opaque frame 40 disposed on the top surface of the carrier body 20 to surround the image-sensing element 30 and a lens 41 connected to the opaque frame 40 and positioned above the image-sensing element 30. For example, the image-sensing module Z further comprises a first conductive unit 5 and a second conductive unit 6. The first conductive unit 5 includes a plurality of first conductive elements 50 electrically connected or contacting between the image-sensing element 30 and the carrier body 20, and the second conductive unit 6 includes a plurality of second conductive elements 60 electrically connected or contacting between the carrier body 20 and the substrate body 10.

Comparing FIG. 4 with FIG. 1, the difference between the fourth embodiment and the first embodiment is as follows: in the fourth embodiment, the carrier unit 2 includes a plurality of first top conductive tracks 200 disposed on the top surface of the carrier body 20, a plurality of first bottom conductive tracks 201 disposed on the bottom surface of the carrier body 20 and respectively corresponding to the first top conductive tracks 200, a plurality of first outer conductive tracks 202 disposed on the top surface of the carrier body 20 and respectively corresponding to the first bottom conductive tracks 201, a plurality of first inner conductive channels 203 embedded in the carrier body 20, and a plurality of first outer conductive channels 204 embedded in the carrier body 20 and separated from the first inner conductive channels 203 by a predetermined distance. Moreover, each first inner conductive channel 203 is electrically connected or contacting between each corresponding first top conductive track 200 and each corresponding first bottom conductive track 201, each first outer conductive channel 204 is electrically connected or contacting between each corresponding first bottom conductive track 201 and each corresponding first outer conductive track 202.

Of course, the carrier unit 2 of the fourth embodiment not only can be applied to the first embodiment, but also can be applied to the second or the third embodiment. Therefore, each conductive pad 300 of the image-sensing element 30 can be electrically connected to each corresponding second bottom conductive track 100 through each corresponding first conductive element 50, each corresponding first top conductive track 200, each corresponding first inner conductive channel 203, each corresponding first bottom conductive track 201, each corresponding first outer conductive channel 204 and each corresponding first outer conductive track 202 and each corresponding second conductive element 60 in sequence.

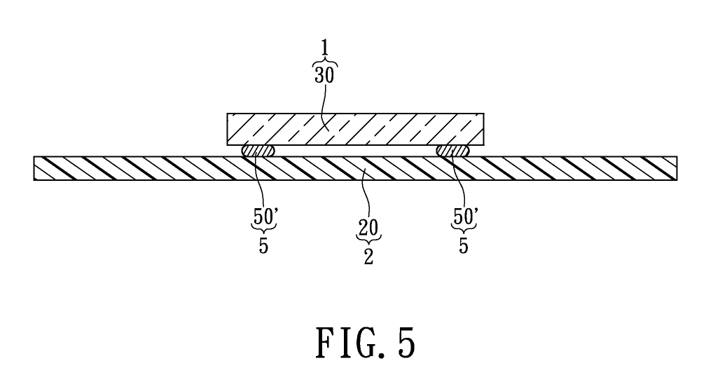

Referring to FIG. 5, the first conductive unit 5 includes a plurality of first conductive elements 50′ (such as solder balls or solder paste) electrically connected or contacting between the image-sensing element 30 and the carrier body 20. Hence, the image-sensing element 30 can be electrically connected to the carrier body 20 through the first conductive elements 50 (as shown in FIG. 1 to FIG. 4) or the first conductive elements 50′ (as shown in FIG. 5).

In conclusion, the substrate body, the image-sensing element and the opaque frame are disposed on the top surface of the carrier body, thus the whole thickness of the image-sensing module can be reduced effectively.

The above-mentioned descriptions merely represent the preferred embodiments of the instant disclosure, without any intention or ability to limit the scope of the instant disclosure which is fully described only within the following claims Various equivalent changes, alterations or modifications based on the claims of instant disclosure are all, consequently, viewed as being embraced by the scope of the instant disclosure.

What is claimed is:

1. An image-sensing module for reducing its whole thickness, comprising:
a substrate unit including a substrate body and at least one through opening passing through the substrate body;
a carrier unit including a carrier body disposed on the bottom surface of the substrate body and corresponding to the at least one through opening, wherein the carrier body is electrically connected to the substrate body;
an image-sensing unit including at least one image-sensing element disposed on the top surface of the carrier body and embedded in the at least one through opening, wherein the at least one image-sensing element is electrically connected to the carrier body and surrounded by the substrate body; and
a lens unit including an opaque frame disposed on the top surface of the carrier body to surround the at least one image-sensing element and a lens connected to the opaque frame and positioned above the at least one image-sensing element.

2. The image-sensing module of claim 1, further comprising: a first conductive unit and a second conductive unit, wherein the first conductive unit includes a plurality of first conductive elements electrically connected between the at least one image-sensing element and the carrier body, and the second conductive unit includes a plurality of second conductive elements electrically connected between the carrier body and the substrate body.

3. The image-sensing module of claim 2, wherein the carrier unit includes a plurality of first top conductive tracks disposed on the top surface of the carrier body, the image-sensing unit includes a plurality of conductive pads disposed on the top surface of the at least one image-sensing element and respectively corresponding to the first top conductive tracks, and each conductive pad of the image-sensing unit is electrically connected to each corresponding first top conductive track of the carrier unit through each corresponding first conductive element.

4. The image-sensing module of claim 3, wherein the substrate unit includes a plurality of second bottom conductive tracks disposed on the bottom surface of the substrate body and respectively corresponding to the first top conductive tracks, and each first top conductive track of the carrier unit is electrically connected to each corresponding second bottom conductive track of the substrate unit through each corresponding second conductive element.

5. The image-sensing module of claim 3, wherein the substrate unit includes a plurality of second bottom conductive tracks disposed on the bottom surface of the substrate body and respectively corresponding to the first top conductive tracks, a plurality of second top conductive tracks disposed on the top surface of the substrate body and respectively corresponding to the second bottom conductive tracks, and a plurality of second inner conductive channels embedded in the substrate body, each second inner conductive channel is electrically connected between each corresponding second bottom conductive track and each corresponding second top conductive track, and each first top conductive track of the carrier unit is electrically connected to each corresponding second bottom conductive track of the substrate unit through each corresponding second conductive element.

6. The image-sensing module of claim 3, wherein the substrate unit includes a plurality of second bottom conductive tracks disposed on the bottom surface of the substrate body and respectively corresponding to the first top conductive tracks, a plurality of second top conductive tracks disposed on the top surface of the substrate body and respectively corresponding to the second bottom conductive tracks, a plurality of second outer conductive tracks disposed on the bottom surface of the substrate body and respectively corresponding to the second top conductive tracks, a plurality of second inner conductive channels embedded in the substrate body, and a plurality of second outer conductive channels embedded in the substrate body, each second inner conductive channel is electrically connected between each corresponding second bottom conductive track and each corresponding second top conductive track, each second outer conductive channel is electrically connected between each corresponding second top conductive track and each corresponding second outer conductive track, and each first top conductive track of the carrier unit is electrically connected to each corresponding second bottom conductive track of the substrate unit through each corresponding second conductive element.

7. The image-sensing module of claim 2, wherein the carrier unit includes a plurality of first top conductive tracks disposed on the top surface of the carrier body, a plurality of first bottom conductive tracks disposed on the bottom surface of the carrier body and respectively corresponding to the first top conductive tracks, a plurality of first outer conductive tracks disposed on the top surface of the carrier body and respectively corresponding to the first bottom conductive tracks, a plurality of first inner conductive channels embedded in the carrier body, and a plurality of first outer conductive channels embedded in the carrier body, each first inner conductive channel is electrically connected between each corresponding first top conductive track and each corresponding first bottom conductive track, each first outer conductive channel is electrically connected between each corresponding first bottom conductive track and each corresponding first outer conductive track, the image-sensing unit includes a plurality of conductive pads disposed on the top surface of the at least one image-sensing element and respectively corresponding to the first top conductive tracks, and each conductive pad of the image-sensing unit is electrically connected to each corresponding first top conductive track of the carrier unit through each corresponding first conductive element.

8. The image-sensing module of claim 7, wherein the substrate unit includes a plurality of second bottom conductive tracks disposed on the bottom surface of the substrate body and respectively corresponding to the first top conductive tracks, and each first top conductive track of the carrier unit is electrically connected to each corresponding second bottom conductive track of the substrate unit through each corresponding second conductive element.

9. The image-sensing module of claim 7, wherein the substrate unit includes a plurality of second bottom conductive tracks disposed on the bottom surface of the substrate body and respectively corresponding to the first top conductive tracks, a plurality of second top conductive tracks disposed on the top surface of the substrate body and respectively corresponding to the second bottom conductive tracks, and a plurality of second inner conductive channels embedded in the substrate body, each second inner conductive channel is electrically connected between each corresponding second bottom conductive track and each corresponding second top conductive track, and each first top conductive track of the carrier unit is electrically connected to each corresponding second bottom conductive track of the substrate unit through each corresponding second conductive element.

10. The image-sensing module of claim 7, wherein the substrate unit includes a plurality of second bottom conductive tracks disposed on the bottom surface of the substrate body and respectively corresponding to the first top conductive tracks, a plurality of second top conductive tracks disposed on the top surface of the substrate body and respectively corresponding to the second bottom conductive tracks, a plurality of second outer conductive tracks disposed on the bottom surface of the substrate body and respectively corresponding to the second top conductive tracks, a plurality of second inner conductive channels embedded in the substrate body, and a plurality of second outer conductive channels embedded in the substrate body, each second inner conductive channel is electrically connected between each corresponding second bottom conductive track and each corresponding second top conductive track, each second outer conductive channel is electrically connected between each corresponding second top conductive track and each corresponding second outer conductive track, and each first top conductive track of the carrier unit is electrically connected to each corresponding second bottom conductive track of the substrate unit through each corresponding second conductive element.
